(19) United States
(12) Patent Application Publication
(10) Pub. No.: US 2022/0278171 A1
(43) Pub. Date: Sep. 1, 2022

(54) DIODE SYSTEMS AND RELATED METHODS

(71) Applicant: SEMICONDUCTOR COMPONENTS INDUSTRIES, LLC, Phoenix, AZ (US)

(72) Inventors: Derryl ALLMAN, Camas, WA (US); Diann M. DOW, Austin, TX (US)

(73) Assignee: SEMICONDUCTOR COMPONENTS INDUSTRIES, LLC, Phoenix, AZ (US)

(21) Appl. No.: 17/188,466

(22) Filed: Mar. 1, 2021

(51) Int. Cl. H01L 27/24; H01L 29/861; H01L 29/66; H01L 45/00; G11C 13/00; G06N 3/02

(52) U.S. Cl. CPC H01L 27/2409; H01L 29/861; H01L 29/6609; H01L 45/1253; G11C 13/0002; G06N 3/02

(57) ABSTRACT

Implementations of a diode may include a first electrode; a first dielectric layer coupled to the first electrode; a second dielectric layer coupled to the first dielectric layer; and a second electrode coupled to the second dielectric layer. The first dielectric layer may be one of silicon dioxide or aluminum oxide; and the second dielectric layer may be one of niobium oxide, tantalum oxide, zirconium oxide, hafnium oxide, or any combination thereof.

### BACKGROUND

### Technical Field

Aspects of this document relate generally to semiconductor device, such as diodes.

### Background

Semiconductor devices have been devised to transmit, carry, or store electrical charge in various ways. Devices like transistors, for example, are constructed to regulate the flow of electrical charge through the device using a gate structure.

### SUMMARY

Implementations of a diode may include a first electrode; a first dielectric layer coupled to the first electrode; a second dielectric layer coupled to the first dielectric layer; and a second electrode coupled to the second dielectric layer. The first dielectric layer may be one of silicon dioxide or aluminum oxide; and the second dielectric layer may be one of niobium oxide, tantalum oxide, zirconium oxide, hafnium oxide, or any combination thereof.

Implementations of a diode may include one, all, or any of the following:

The second electrode may be directly coupled to the second dielectric layer.

The second electrode may be coupled to the second dielectric layer through the first dielectric layer.

The second electrode may extend around both the first dielectric layer and the second dielectric layer and around at least a portion of the first electrode.

The second electrode may be an electrode included in a resistive nonvolatile memory resistive random access memory bit cell.

The diode may be coupled above a nonvolatile memory bit cell formed in silicon in a semiconductor device layer stack.

The diode may be coupled between a device and a ground plane interconnect.

The material of the second dielectric layer may change a diode voltage in response to a change in temperature of the diode.

The diode may form a programmed bit in a one time programmable block cell.

Implementations of a neural network system may include an input layer of one or more input nodes; one or more electrical connections coupling each of the one or more input nodes with one or more hidden nodes of a hidden layer; and an output layer of one or more output nodes coupled with one or more of the hidden nodes of the hidden layer. An interconnect diode may be coupled electrically between each of the one or more input nodes of the input layer and each of the one or more hidden nodes of the hidden layer.

Implementations of a neural network system may include one, all, or any of the following:

The interconnect diode may include: a first electrode; a first dielectric layer coupled to the first electrode; a second dielectric layer coupled to the first dielectric layer; and a second electrode coupled to the second dielectric layer. The first dielectric layer may be one of silicon dioxide or aluminum oxide; and the second dielectric layer may be one of niobium oxide, tantalum oxide, zirconium oxide, hafnium oxide, or any combination thereof.

The system may include an interconnect diode coupled electrically between each of the one or more hidden nodes of the hidden layer and each of the one or more output nodes of the output layer.

The system may include a second hidden layer of hidden nodes coupled with a corresponding plurality of interconnect diodes.

The second electrode may be one of directly coupled to the second dielectric layer or coupled to the second dielectric layer through the first dielectric layer.

The neural network system may include a compute-in-analog semiconductor device.

The second electrode may extend around both the first dielectric layer and the second dielectric layer and around at least a portion of the first electrode.

Implementations of a method of forming an interconnect diode may include forming a first electrode; depositing a first dielectric layer coupled to the first electrode; depositing a second dielectric layer coupled to the first dielectric layer; and forming a second electrode coupled to the second dielectric layer. The method may also include forming an interconnect coupled to one of the first electrode or the second electrode. The first dielectric layer may be one of silicon dioxide or aluminum oxide; and the second dielectric layer may be one of niobium oxide, tantalum oxide, zirconium oxide, hafnium oxide, or any combination thereof.

Implementations of a method of forming an interconnect diode may include one, all, or any of the following:

The second electrode may be directly coupled to the second dielectric layer.

The second electrode may be coupled to the second dielectric layer through the first dielectric layer.

The second electrode may extend around both the first dielectric layer and the second dielectric layer and around at least a portion of the first electrode.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of a first implementation of an interconnect diode;

FIG. 2 is a cross sectional view of a second implementation of a interconnect diode;

FIG. 3 is a cross sectional view of a third implementation of an interconnect diode;

FIG. 4 is a diagram of an implementation of a neural network system;

FIG. 5 is a cross sectional view of a implementation of an interconnect diode system including a nonvolatile memory bit cell;

FIG. 6 is a cross sectional view of a implementation of an interconnect diode system including a silicon nonvolatile memory bit cell;

FIG. 7 is a cross sectional view of a implementation of an interconnect diode system employed in an antenna system;

FIG. 8 is a cross sectional view of a implementation of an interconnect diode system where the interconnect diode is used as a temperature sensor;

FIG. 9 is a cross sectional view of an implementation of a interconnect diodes system where the interconnect diode is used as a one-time programmable bit cell;

FIG. 10 is a graph of the temperature characteristic of an implementation of an interconnect diode showing the diode voltage variation curve at various temperatures;

FIG. 11 is a graph of current density versus applied voltage for various implementations of unidirectional interconnect diodes;

FIG. 12 is a diagram of another neural network implementation;

FIG. 13 is a diagram of the input and outputs of a neural network implementation;

FIG. 14 is a diagram of nodes and weights of a neural network implementation;

FIG. 15 is an electrical diagram of the system in FIG. 14; and

FIG. 16 is an electrical diagram of a neural network system comprising interconnect diodes.

### DESCRIPTION

This disclosure, its aspects and implementations, are not limited to the specific components, assembly procedures or method elements disclosed herein. Many additional components, assembly procedures and/or method elements known in the art consistent with the intended diodes and related methods will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such diode systems and related methods, and implementing components and methods, consistent with the intended operation and methods.

The various diode implementations disclosed in this document may be either unidirectional (charge flow in all one direction) or bidirectional (charge flow in either of two directions). This ability of the diode implementations disclosed in this document to be bidirectional as well as unidirectional is unique compared to diodes made of silicon which are unidirectional diodes. The various diode implementations discussed in this document are referred to as interconnect diodes. As used herein, an interconnect diode is a diode that physically resides in/along structure used to connect (interconnect) to a device or metallic traces. Various implementations of interconnect diodes and methods of forming such diodes will be discussed in this document in the context of various use conditions and use structures. Because the diodes are formed in the interconnect region the diodes may be substantially independent of any latchup considerations because they are insulated/isolated from each other by the interlayer dielectric material in which the interconnect diodes are located. Furthermore, because of the structure of the diodes, the materials of the diodes, and their placement in the interconnect any parasitics from the interconnect diodes may be very minimal.

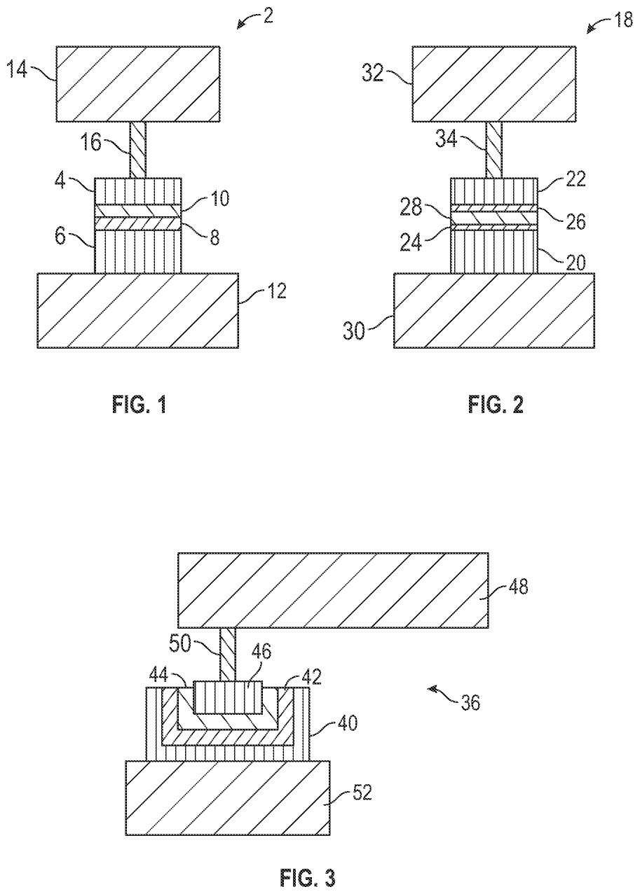

Referring to FIG. 1, a first implementation of an interconnect diode 2 is illustrated. As illustrated, the interconnect diode 2 includes an upper electrode (first electrode) 4 and a lower electrode (second electrode) 6. In between the electrodes, 4, 6 is a first dielectric layer 8 coupled to a second dielectric layer 10. In various implementations, the second dielectric layer 10 may be referred to as a semiconductive layer as the material acts as a partially electrically conductive dielectric that exhibits a voltage drop (like a resistor) across the layer. In various implementations, either the first dielectric layer 8 or the second dielectric layer 10 may include a material that exhibits the semiconductive behavior. Which layer includes the semiconductive dielectric material is selected by the preferred direction of current flow through the interconnect diode 2.

The materials of the first electrode and second electrode may be titanium nitride, tantalum nitride, or aluminum in various implementations though other electrically conductive materials may be employed in various implementations. In various implementations, the material of the first dielectric layer 8 may be, by non-limiting example, silicon dioxide, aluminum oxide, or a combination of silicon dioxide and aluminum oxide. In various implementations, the material of the second dielectric layer 10 may be, by non-limiting example, niobium oxide, tantalum oxide, or zirconium oxide, hafnium oxide, or any combination of the foregoing. The use of the two different materials for the material of the first dielectric layer 8 and the second dielectric layer 10 enables the ability to form both unidirectional and bidirectional diode designs. The diode implementation illustrated in FIG. 1 is a unidirectional diode as charge can only flow in one direction across the diode 2. As illustrated, the lower electrode 6 of the diode to is directly coupled to a lower interconnect 12 while the upper electrode 4 is coupled to an upper interconnect 14 by via/trace 16.

Referring to FIG. 2, a second implementation of an interconnect diode 18 is illustrated. Similar to the diode 2 of FIG. 1, this diode designed also includes a lower electrode (second electrode) 20 and upper electrode (first electrode) 22 with dielectric material between them. In this case the material of the first dielectric layer is divided into two portions 24, 26 each of which are directly coupled to the upper electrode 22 into the lower electrode 20, respectively. In between the two portions 24, 26 is the material of the second dielectric layer 28. The materials for the portions 24, 26 of the first dielectric layer and for the second dielectric layer 28 may be any disclosed for these layers in this document. In various implementations, the portions 24, 26 may include semiconductive dielectric materials while the second dielectric layer 28 may include a dielectric material. However, in other implementations, the second dielectric layer 28 may include the semiconductive dielectric material while the portions 24, 26 may include a dielectric material. Because the material of the first dielectric layer is divided on either side of the material of the second dielectric layer 28, the diode implementation illustrated in FIG. 2 is bidirectional allowing current/charge to flow in either direction through the device. A bidirectional diode does not have a forward bias capability but is responsive to positive or negative swings in voltage. The use of bidirectional diodes may allow the interconnect diode to made agnostic to circuit potentials the diode experiences during operation. In the interconnect diode 18 of FIG. 2, the lower electrode 20 is directly coupled to lower interconnect 30 while the upper electrode 22 is coupled to upper interconnect 32 through via 34. In various implementations, because the first dielectric layer is divided into portions 24, 26, the second electrode is coupled to the second dielectric layer through one of the portions of the first dielectric layer. In these implementations the first dielectric layer may include a semiconductive dielectric material like any disclosed in this document. In the diode implementations illustrated in FIG. 1 and FIG. 2 an additional interlayer dielectric material fills the space around the diodes 2, 18 between the lower interconnects and upper interconnects of both devices though this area is indicated as being empty in the drawings for the sake of illustration.

FIG. 11 illustrates various trend lines for the current density through various implementations of interconnect diodes at different forward and reverse bias voltage values. The various implementations of interconnect diodes vary depending upon the respective ratio of the thicknesses of aluminum oxide and tantalum oxide used in each diode. The structure of the interconnect diodes used in FIG. 11 is that illustrated in FIG. 1 as the diodes are unidirectional. As can be seen in FIG. 11, as the forward and reverse bias voltages increase, eventually a breakdown voltage is reached where the current density goes to zero. In the graph, a value of 1 for the thickness represents a 30 nm thickness of the material. As illustrated FIG. 11, increasing the thickness of the material of the second dielectric layer serves to increase both the forward and reverse breakdown voltages of the diode. This allows for tailoring/controlling/determining of the breakdown voltage and thus the protection voltage for components in a given circuit in which the interconnect diode. This control of the breakdown voltage is carried out by changing the relative thickness of the first dielectric layer and a second dielectric layer during manufacturing of the diode.

In various implementations of a method of forming an interconnect diode like those illustrated in FIG. 1 and FIG. 2, the method may include depositing a sheet film that includes aluminum. In various method implementations, prior to the definition of interconnect or traces in the material of the sheet film, deposition of a titanium nitrate or a tantalum nitride layer is then carried out to form the material of the bottom electrode. The material of the first dielectric layer and the material of the second dielectric layer are then deposited using atomic layer deposition (ALD). For the implementation of the interconnect diode structure illustrated in FIG. 1, the material of the first dielectric layer may be deposited as a single layer first using atomic layer deposition followed by the ALD deposition of the material of the second dielectric layer. For the implementation of the interconnect diodes structure illustrated in FIG. 2, the deposition of the material of the first dielectric layer may take place in two separate steps, a first initial step to form the first portion 24 followed by a deposition step for the material of the second dielectric layer then followed by a second deposition step to form the second portion 26 of the first dielectric layer. Various other method implementations involving more than three layers of dielectric materials and more than two dielectric materials may be constructed using the principles disclosed in this document by those of ordinary skill in the art.

Following deposition of the first and second dielectric layers, the material of the top electrode is then deposited which may be any electrode material disclosed in this document. Following these deposition steps, a patterning process involving photolithography is employed to pattern the locations where the interconnect diodes will be formed. An etching step is then used to remove material around the diode locations leaving each diode directly coupled to the lower interconnect containing aluminum. Following removal of the patterning material above the material of the diode, an additional patterning step involving photolithography is used to form the structure of the traces/interconnects in the aluminum-containing sheet film. An interlayer dielectric material is then deposited over the diodes which is then patterned to form the via structures followed by planarizing prior to deposition of another sheet film that forms the upper interconnect. In this way the structure of the diode is formed as part of an interconnect/via between the material of the upper and lower interconnects/metal layers. This particular implementation of a method of forming an interconnect diode may be employed where the material of the upper and lower interconnects contains aluminum and is thus patternable using a reactive ion/plasma etching process.

In various implementations, implementations of interconnect diodes like those disclosed in FIG. 1 and FIG. 2 may be made using electrode materials that include copper. As such implementations the lower electrode may include a barrier metal such as tantalum nitride coupled with the copper to prevent the diffusion of the copper into the electric material of the diode itself. The copper interconnects may be formed using a dual damascene process. However, the material of the diode is still formed using a photolithography plasma etch process like any disclosed herein.

Referring to FIG. 3, a third implementation of an interconnect diode 36 is illustrated. As illustrated, the diode 36 includes a lower electrode (second electrode) 40 which wraps around the material of the first dielectric layer 42 and the material of the second dielectric layer 44. In the implementation illustrated in FIG. 3, the material of the lower electrode 40 completely wraps around the first dielectric layer 42 and the second dielectric layer 44. In various implementations the material of the first dielectric layer 42 may be a resistor dielectric layer like any disclosed in this document. In other implementations however, the material of the lower electrode 40 may not completely or may only substantially wrap around the material of the first dielectric layer 42 and the second dielectric layer 44. The diode 36 also includes an upper electrode 46 which is coupled to an upper interconnect 48 through via 50. As illustrated, the material of the lower electrode 40 is coupled directly to a lower interconnect 52. The interconnect diode implementation illustrated FIG. 3 has increased diode area when compared to the implementations illustrated in FIG. 1 and FIG. 2 which allows for increased current through the diode. The area between the upper interconnect 48 and lower interconnect 52 is filled with an interlayer dielectric though it is not shown in figure similar to the implementations illustrated in FIG. 1 and FIG. 2. The diode illustrated in FIG. 3 is a unidirectional diode. However in various implementations the material of the first dielectric layer 42 could be divided into two portions and deposited on either side of the material of the second dielectric layer 44 to form a bidirectional diode using the principles discussed with respect to the implementation illustrated in FIG. 2.

In various implementations of methods of forming interconnect diodes implementations like those illustrated in FIG. 3, the method begins following definition of the upper interconnect and lower interconnect layers and deposition of capping films which may be silicon nitride or silicon carbide in various implementations. In between the upper interconnect and the lower interconnect layers is the interlayer dielectric material and the method includes using a photolithography and etching step to open of the cavity in the interlayer dielectric material where the diode will be located as part of forming an interconnect between the upper interconnect 48 and lower interconnect 52. Following creating the cavity using the etching process the material of the lower electrode is deposited into the cavity followed by atomic layer deposition of the material of the first dielectric layer 42 and the material of the second dielectric layer 44. In various method implementations the material of the first dielectric layer 42 may be deposited in one layer 4 may be divided into 2 separate deposition steps on either side of a deposition step that deposits the material of the second dielectric layer 44. In various method implementations the material of the upper electrode 46 is then deposited into the remaining space in the cavity. In various method implementations the material of the diode is then planarized. In various other implementations and etching step may be used to define the boundaries of the diode prior to the planarizing step. The material of the via is also deposited using a patterning step followed by a planarizing step in various implementations. The diode structure illustrated in FIG. 3 may be particularly useful where a copper-containing material is being used to form the upper interconnect 48 and lower interconnect 52 and the pattern of the interconnects cannot be made using plasma etching but is formed using an plating process.

Implementations of interconnect diodes like those disclosed in this document may be included in a wide variety of circuit structures and included as part of other devices. Various implementations will be discussed subsequently.

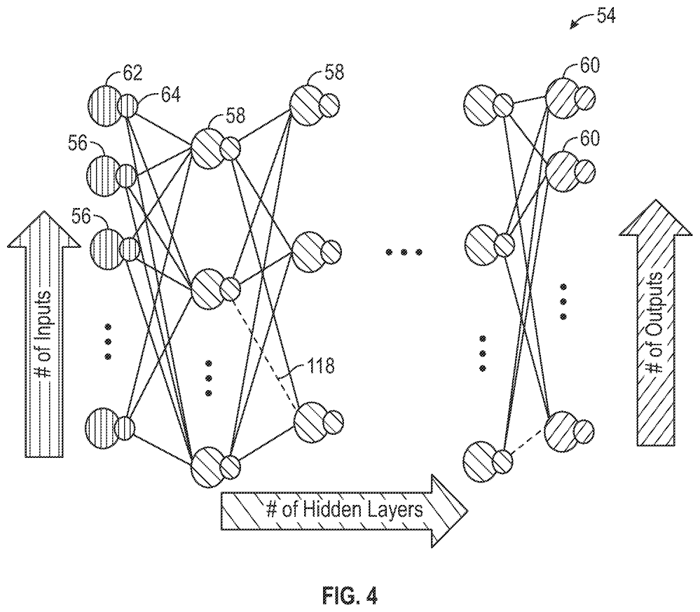

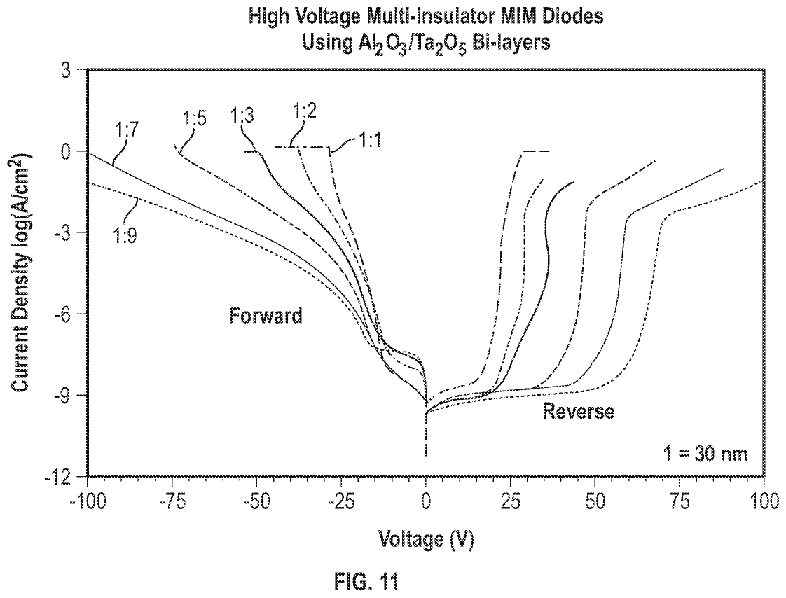

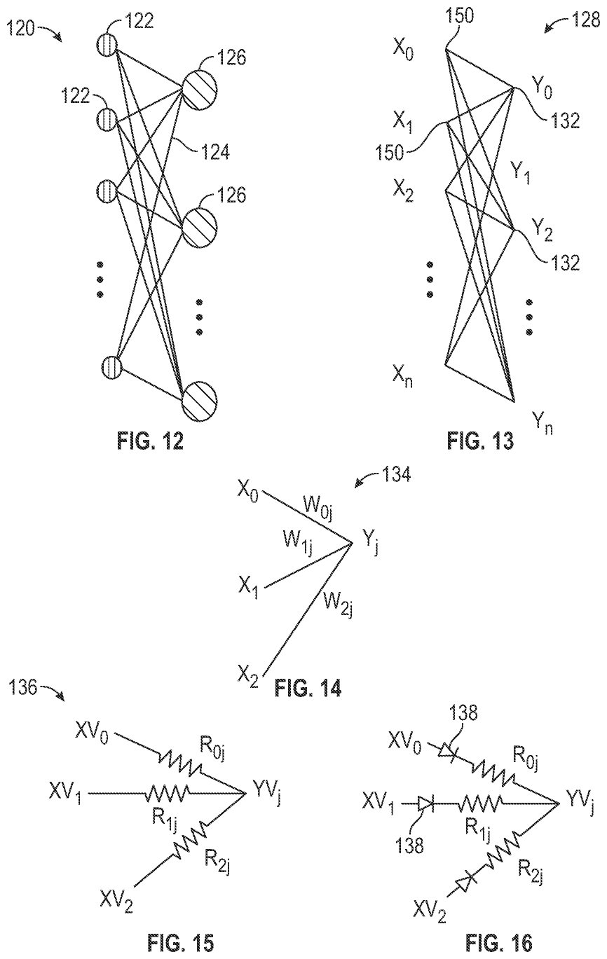

Referring to FIG. 4, an implementation of a neural network system 54 that employs interconnect diodes like any disclosed in this document is illustrated. As illustrated, the neural network system 54 includes an input layer of nodes 56, one or more layers of hidden nodes 58, and a layer of output nodes 60. In the diagram illustrated in FIG. 4, each node includes one or more inputs represented by the largest circle 62 and then a transformed value represented by the smaller circle 64 representing the work of each node to transform the inputs using one or more weights. In a particular implementation, each node may sum the inputs and apply the weights to produce the transformed value. In the diagram illustrated in FIG. 4, three hidden layers of nodes 58 are included. Also as illustrated in diagram. Each node may be densely connected where each node is connected to each other node in the layer of nodes preceding it in the network or one or more nodes may be sparsely connected where each node connected to only a predetermined number of the nodes in the preceding layer. The dotted line connection 118 is used to indicate that this connection between these nodes may not be used in a particular sparsely connected neural network model design. Referring to FIG. 12, the sequence of operations performed by each node and/or layers of nodes may be varied between each set/layer of nodes. In this implementation of a neural network 120, the inputs from each node of a first layer of input nodes 122 are each multiplied by a weight as indicated by each line 124 and in each input is summed as indicated by the larges circle 126. Referring to FIG. 13, a corresponding mathematical representation 128 of the neural network of FIG. 12 is illustrated.

Mathematically, as illustrated in FIG. 13, the input received at each node is represented by Xᵢ. Each node 130 of the input layer is densely connected to each node of the layer of summation nodes 132 designated in FIG. 4 as Yᵢ. The connection between each of the input nodes 130 and this summation nodes 132 is illustrated in FIG. 14. As illustrated, each input X₀, X₁, X₂ is multiplied by a corresponding weight W₀ⱼ, W₁ⱼ, W₂ⱼ and then summed to form output Yⱼ. This process is repeated throughout the network at each layer of nodes within the network. FIG. 15 illustrates an electrical equivalent 136 to the mathematical representation 134 illustrated in FIG. 14. Here, the set of inputs are a set of voltages X_{V0}, X_{V1}, X_{V2} from input nodes that each pass through a corresponding resistance R₀ⱼ, R₁ⱼ, R₂ⱼ and are then summed to a single voltage value Y_{Vj}. In electrical implementations of neural networks like those disclosed herein, Kirchhoff's. voltage or current laws are used to solve for the summed voltage at each node. In various system implementations, a wide variety of resistor types could be used to create both fixed and variable resistance values which permit the weights to be changed and/or set as desired. By non-limiting example, various resistor devices may be employed such as variable resistors, fixed resistors, a nonvolatile memory, resistive memory devices, an interconnect diode-containing device like those disclosed in this document, or any other resistive device demonstrating a fixed or variable resistance value. In various system implementations, the voltage calculation may be carried out digitally or in analog. For digital calculations various logic elements are used to allow the inputs to be summed and multiplied by the weights.

In analog implementations, however, the approach may be structurally simplified considerably by using a digital-to-analog converter to convert the input voltages to an analog voltage signal(s), process the analog voltage signal(s) through the neural network, and then process the resulting analog voltage signal(s) back to digital using an analog-to-digital converter. In this way the operation and construction of a neural network may be considerably simplified in terms of the number of electrical components required to carry out the operation. In addition, the ability to perform the neural network computations in analog may reduce the amount of computing power and/or the amount of electrical power required to carry out a particular neural network operation. For example, the ability to carry out the neural network in an physical electrical system may permit the optimization of memory access for convolution during networks or the optimization of digital-to-analog an analog-to-digital signal processing for the various inputs and outputs. In various system implementations, each of the voltage inputs may be a 32 bit, 16 bit, 8 bit, 4 bit, 2 bit or single bit (or greater number of bits) digital signal converted to an analog voltage signal as the use of the analog signals permits a corresponding reduction of the number of inputs needed for neural network processing.

Referring to FIG. 16, the system of FIG. 15 containing an interconnect diode 138 and between the voltage and a resistor is illustrated. One of the challenges of using a system 136 like that illustrated in FIG. 15 is that there is a risk that if the summed voltage Y_{Vj} is greater than any one of the input voltages the current may reverse and flow back to the input preventing the proper operation of the system. In other system implementations where a current source(s) is contained in or feeds into the summed node Y_{Vi}, a similar situation may be created where current flow can reverse into one or more of the input notes. To prevent this, the use of the input diodes 138 allows current flow only to the summed node Y_{Vj} thus ensuring the electrical integrity of each node and the network. An additional purpose of using the interconnect diodes 62 may be to prevent crosstalk between different summation nodes during operation of the system. Any of the various interconnect diode implementations disclosed in this document may be employed in the neural network implementations disclosed herein. In various implementations the use of three dimensional memory may be employed to make the connections between the various nodes and/or implement the variable/fixed resistances.

Various neural network models, designs, and node structures may be developed using the principles disclosed in this document to employ interconnect diodes to allow for the creation of various compute-in-analog devices. These compute-in-analog devices may take the form of an application specific integrated circuit (ASIC) specifically designed to implement, by non-limiting example, a particular neural network model, a family of neural network models, or a flexibly selectable set of neural network models. A wide variety of neural network types may be implemented in such a compute-in-analog device such as, by non-limiting example, a feed forward neural network, a convoluted neural network, a recurrent neural network, reinforcement learning models, and any other neural network type that employs weights and/or summation nodes. These various neural network implementations made include any number of input nodes connected densely or sparsely with any number of hidden layers and any number of output nodes. In various system implementations, the use of 2, 3, or 4 hidden layers may be sufficient for many applications. In others, additional hidden layers may be employed the pending upon the complexity of the task being attempted. In various other system implementations, various combinations of compute-in-analog devices may be combined in various ways to allow the system to work cooperatively in, by non-limiting example, a series relationship, a parallel relationship, or both a series and a parallel relationship.

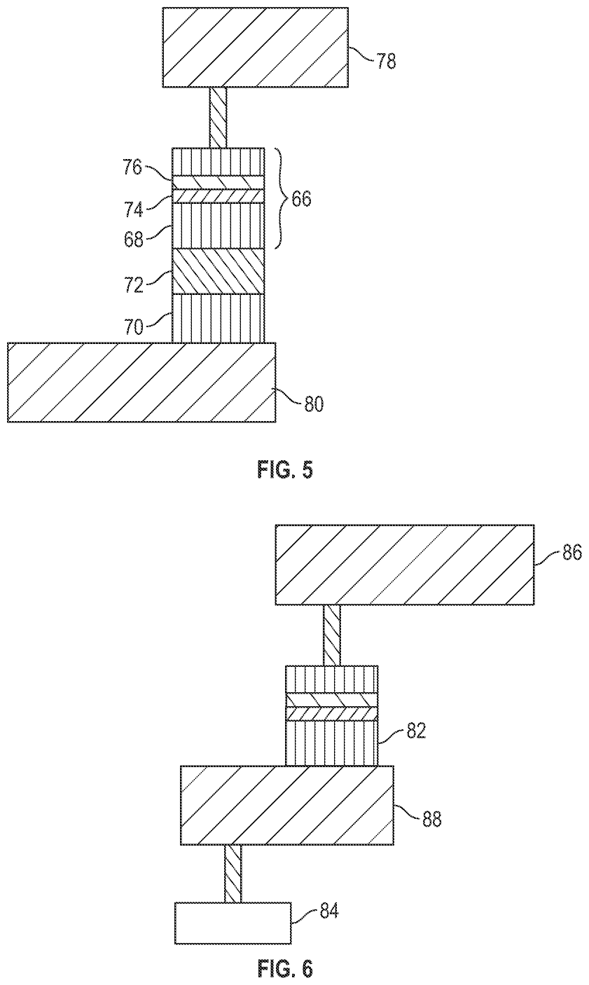

In other implementations of interconnect diodes, the diode may be partly or fully integrated into another device present in the interconnect pathway between two different traces or connectors. Referring to FIG. 5, an implementation of a interconnect diode 66 is illustrated which has a shared electrode with a nonvolatile memory resistive random access memory bit cell. As illustrated, the resistive random access memory cells includes an upper electrode 68 and a lower electrode 70 with a filament film 72 coupled between them. The upper electrode 68 of the bit cell also functions as the lower electrode of the interconnect diodes 66 in this implementation, the first dielectric material 74 in the diode 66 may be an aluminum oxide material and the material of the second dielectric layer 76 may be a layer of tantalum oxide. In other implementations however, the upper electrode may not be shared. In particular implementations the second dielectric layer may be referred to as a resistive layer. In this way, the electrical benefits of having the diode are combined with the resistive random access memory cell within the same interconnect between the upper trace 78 and lower trace 80. Again, in this implementation, a dielectric material is present between the upper trace 78 and lower trace 80 but is not shown for purposes of illustration in this drawing.

The ability to use interconnect diodes like those disclosed herein may allow the diodes to be integrated with silicon devices simply by including them in an interconnect that couples with the silicon device. Referring to FIG. 6, an implementation of a interconnect diode 82 is illustrated coupled in an interconnect path to a silicon nonvolatile memory bit cell 84. As can be observed from inspection, the flow of electricity between the upper trace 86 down through the diode 82 to the lower trace 88 to the silicon nonvolatile memory bit cell 84 occurs only through the interconnect diode 82. In this implementation, the interconnect diode is being used in an aluminum based analog memory that employs various silicon nonvolatile memory bit cells. In this implementation the use of interconnect diodes to replace silicon diodes used in the analog aluminum based memory to direct current flow between various resistive memory nodes may prevent crosstalk between the different nodes. The use of the interconnect diodes permits a minimization of the analog memory bit cell area because the diodes are now present in the interconnect area rather than requiring silicon space.

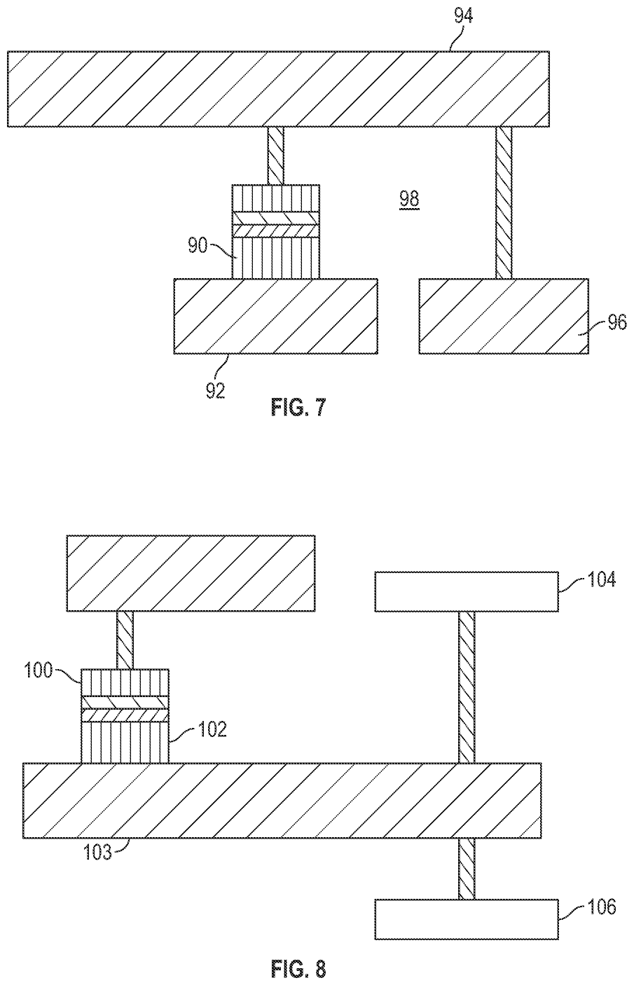

In the fabrication of the integrated circuit containing silicon diodes there can be a buildup of charge an interconnect lines that can damage the circuit. The use of interconnect diodes, allow for the current to be conducted to ground before damage occurs. The use of silicon diodes introduces parasitic capacitance which can degrade the performance of protected circuits. In various radio frequency applications, antenna regulations/design rules may require the use of silicon diodes to dissipate any buildup of charge to a ground for long interconnect lines. The use of silicon based diodes can clog routing channels and results in consumption of silicon area on a semiconductor die. The ability to use interconnect diodes like those disclosed herein can replace silicon diodes and still provide connection to the grounding system/grounding tree in a nearby interconnect layer within the device. This can save silicon space and may also reduce the number of design blocks needed. This may allow for better optimization of interconnect routing and a more condensed final circuit design. Referring to FIG. 7, an implementation of an interconnect diode 90 is illustrated coupled in the interconnect between a path to a ground plane 92 and interconnect signal line to a device 94, 96. From inspection, because the interconnect diode 90 is located in the interlayer dielectric area between the ground plane 92 and the interconnect signal to the device along signal line 94, no silicon area is needed to make the connection between the signal line and the ground plane thus reducing the size of the diode cell 98 which includes the interlayer dielectric material (not shown). In very implementations, the interconnect diode 90 can be placed on any interconnect level in the device in a path used to connect a signal line 94 to a ground signal tree/ground plane 92.

In various semiconductor devices, the interconnect diodes is part of the metal interconnect which carries heat away from the circuit components. The interconnect diode materials are sensitive to temperature changes and can accordingly be used as a sensor in a particular semiconductor device to adjust power in a particular power domain to potentially reduce aging or prevent faults within the semiconductor die. Various circuit designs do not have a direct measure of temperature for interconnects so power and aging models of semiconductor die may be inadequate and imprecise requiring over design or leading to the creation of undetectable reliability weaknesses in the die, motherboards, or products. Referring to FIG. 8, an implementation of a interconnect diode 100 functioning as a temperature sensor for an interconnect or circuit is illustrated. As illustrated, the lower electrode 102 of the interconnect diode 100 is directly coupled to interconnect 103 which may be a signal line, a VDD interconnect, or a source of a field effect transistor. As illustrated the interconnect 103 may be coupled via a network to a circuit 104 and/or source of a field effect transistor 106. The diode 100 is illustrated coupled to a temperature sensor network included in the semiconductor die which monitors the change in voltage of the diode and uses a correlation of the voltage change to temperature to calculate a temperature of the interconnect 103.

In various implementations, as all layers of the interconnect system to carry heat the temperature of the interconnect 103 is representative of the heat flow for a particular interconnect system at a particular location. It must be understood that the interconnect diode can be placed at a wide variety of different locations within a given interconnect system and is not limited to just one particular interconnect layer.

The ability to use the interconnect diode 100 to directly monitor and report an accurate temperature of the interconnect during operation of the semiconductor die may permit more accurate modeling. In some implementations, the diode 100 could potentially be used as a protection device for over temperature condition of the semiconductor die where conduction of the diode could be used to provide a signal to a power regulation circuit which may, in response, shutdown the system, put the system into a sleep mode, or reduce the system power. In various implementations, the system may function as aging control for a segmented trench field effect transistor. In various implementations, interconnect diodes could be spread about the structure of the power transistor system and may be used to control local power to distribute temperature uniformly across the power transistor die with a power transistor package. In various implementations, the ability to control and distribute temperature uniformly may be important particular for flip chip packages. In various implementations the power transistor may be a trench field effect transistor. The ability to distribute and control temperatures using interconnect diodes may be used to minimize local self-heating for various digital and analog technologies and processes. The various digital and analog technologies and processes may include devices that do not employ just silicon but could include, by non-limiting example, gallium nitride, gallium arsenide, silicon carbide, sapphire, ruby, silicon on insulator, glass, or any other semiconductor substrate type. A wide variety of semiconductor device types may also employ interconnect diodes for temperature monitoring including, by non-limiting example, metal oxide semiconductor devices, double diffused metal oxide semiconductor field effect transistors, laterally diffused metal oxide semiconductor devices, fin field effect transistor devices (FinFETs), bipolar complementary metal oxide semiconductor devices, emitter coupled logic bipolar logic devices, gallium nitride transistors, silicon carbide field effect transistor, silicon carbide metal oxide semiconductor devices, silicon carbide trench field effect transistors, silicon carbide diodes, and any other semiconductor device type. In various implementations, the use of the interconnect diodes may be used as a test vehicle for the development of thermal models for various devices and/or packages.

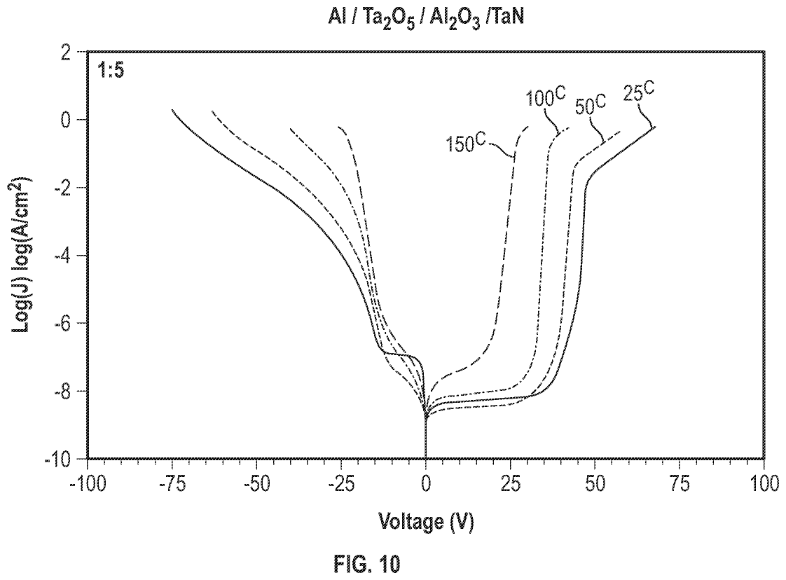

FIG. 10 is a graph illustrates the voltage response of a diode that includes aluminum, tantalum oxide, aluminum oxide, and tantalum nitride as a stack in a 1:5 ratio showing the effect on the diode voltage and current response at 4 different temperatures, 25 C, 50 C, 100 C, and 150 C. At a constant voltage level in either forward or reverse conditions, the leakage current of the interconnect diode increases with temperature which allows for temperature monitoring for the interconnect line or subsequent circuit to which the diode is coupled below. In various implementations, the device system of FIG. 8 could be used as a temperature sensor for Internet Of Things applications to measure an external ambient temperature as well using similar principles. Various materials disclosed herein used as second dielectric materials may have a significantly steeper temperature response curves and silicon dioxide or aluminum dioxide allowing, by non-limiting example, hafnium oxide, zirconium oxide, tantalum oxide, or niobium oxide to function as temperature sensing components.

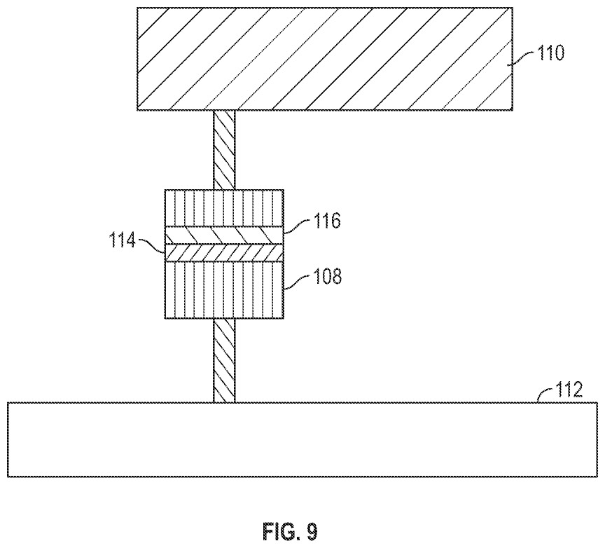

Referring to FIG. 9, an implementation of a interconnect diode 108 included as part of a one-time programmable bit cell is illustrated. In this implementation the interconnect diode 108 is the one time programming device of the bit cell. At the higher voltage levels illustrated in FIG. 10, there is an observable change in the current response indicating a change in the dielectric material 2 to rupture or leakage. This observable change in current response subsequently provides a different current response when voltage is applied to the interconnect diode which permits the interconnect diode to be recognized as a programmed bit. The use of the interconnect diode may provide a smaller one-time programmable block since the interconnect diode can be stacked above or below and interconnect line. The programming of the interconnect diode is done by reverse biasing the interconnect diode to voltage levels beyond the point at which the current response changes or to a total breakdown of the diode. In particular implementations the first dielectric layer material may be aluminum oxide. Because the thickness of the aluminum oxide film in the thickness of the first interconnect layer can be tuned using manufacturing, the resulting structure can be changed to provide different voltage level responses. This interconnect diode type may be used with any voltage range for a circuit making its manufacture technology agnostic. This may be particular so when varying ratios between the thicknesses of the first dielectric layer 114 and the second dielectric layer 116 may be used to tune the breakdown voltage of the interconnect diode 108. This tuning of the breakdown voltage using ratios of thickness may be similar to that previously described in this document.

In various implementations, the various interconnect diodes may be referred to as metal-insulator-insulator-metal diodes.

In places where the description above refers to particular implementations of interconnect diodes and implementing components, sub-components, methods and sub-methods, it should be readily apparent that a number of modifications may be made without departing from the spirit thereof and that these implementations, implementing components, sub-components, methods and sub-methods may be applied to other interconnect diodes.

What is claimed is:

1. A diode comprising:
a first electrode;
a first dielectric layer coupled to the first electrode;
a second dielectric layer coupled to the first dielectric layer; and
a second electrode coupled to the second dielectric layer;
wherein the first dielectric layer is one of silicon dioxide or aluminum oxide; and
wherein the second dielectric layer is one of niobium oxide, tantalum oxide, zirconium oxide, hafnium oxide, or any combination thereof.

2. The diode of claim 1, wherein the second electrode is directly coupled to the second dielectric layer.

3. The diode of claim 1, wherein the second electrode is coupled to the second dielectric layer through the first dielectric layer.

4. The diode of claim 1, wherein the second electrode extends around both the first dielectric layer and the second dielectric layer and around at least a portion of the first electrode.

5. The diode of claim 1, wherein the second electrode is an electrode comprised in a resistive nonvolatile memory resistive random access memory bit cell.

6. The diode of claim 1, wherein the diode is coupled above a nonvolatile memory bit cell formed in silicon in a semiconductor device layer stack.

7. The diode of claim 1, wherein the diode is coupled between a device and a ground plane interconnect.

8. The diode of claim 1, wherein a material of the second dielectric layer changes a diode voltage in response to a change in temperature of the diode.

9. The diode of claim 1, wherein the diode forms a programmed bit in a one time programmable block cell.

10. A neural network system comprising:
an input layer of one or more input nodes;
one or more electrical connections coupling each of the one or more input nodes with one or more hidden nodes of a hidden layer; and
an output layer of one or more output nodes coupled with one or more of the hidden nodes of the hidden layer;
wherein an interconnect diode is coupled electrically between each of the one or more input nodes of the input layer and each of the one or more hidden nodes of the hidden layer.

11. The system of claim 10, wherein the interconnect diode comprises:
a first electrode;
a first dielectric layer coupled to the first electrode;
a second dielectric layer coupled to the first dielectric layer; and
a second electrode coupled to the second dielectric layer;
wherein the first dielectric layer is one of silicon dioxide or aluminum oxide; and
wherein the second dielectric layer is one of niobium oxide, tantalum oxide, zirconium oxide, hafnium oxide, or any combination thereof.

12. The system of claim 10, further comprising an interconnect diode coupled electrically between each of the one or more hidden nodes of the hidden layer and each of the one or more output nodes of the output layer.

13. The system of claim 12, further comprising a second hidden layer of hidden nodes coupled with a corresponding plurality of interconnect diodes.

14. The diode of claim 11, wherein the second electrode is one of directly coupled to the second dielectric layer or coupled to the second dielectric layer through the first dielectric layer.

15. The diode of claim 10, wherein the neural network system comprises a compute-in-analog semiconductor device.

16. The diode of claim 11, wherein the second electrode extends around both the first dielectric layer and the second dielectric layer and around at least a portion of the first electrode.

17. A method of forming an interconnect diode, the method comprising:
forming a first electrode;
depositing a first dielectric layer coupled to the first electrode;
depositing a second dielectric layer coupled to the first dielectric layer; and
forming a second electrode coupled to the second dielectric layer;
forming an interconnect coupled to one of the first electrode or the second electrode;
wherein the first dielectric layer is one of silicon dioxide or aluminum oxide; and
wherein the second dielectric layer is one of niobium oxide, tantalum oxide, zirconium oxide, hafnium oxide, or any combination thereof.

18. The method of claim 17, wherein the second electrode is directly coupled to the second dielectric layer.

19. The method of claim 17, wherein the second electrode is coupled to the second dielectric layer through the first dielectric layer.

20. The method of claim 17, wherein the second electrode extends around both the first dielectric layer and the second dielectric layer and around at least a portion of the first electrode.
